(19) United States
(12) Patent Application Publication
(10) Pub. No.: US 2015/0180448 A1
(43) Pub. Date: Jun. 25, 2015

(54) RESONATOR ELEMENT, ELECTRONIC DEVICE, ELECTRONIC APPARATUS, AND MOVING OBJECT

(71) Applicant: Seiko Epson Corporation, Tokyo (JP)

(72) Inventor: Fumio ICHIKAWA, Suwa (JP)

(21) Appl. No.: 14/574,636

(22) Filed: Dec. 18, 2014

(30) Foreign Application Priority Data
Dec. 19, 2013 (JP) 2013-262136

(51) Int. Cl. H03H 9/21

(52) U.S. Cl. CPC H03H 9/21

(57) ABSTRACT

A resonator element inhibiting an unwanted vibration such as a torsional vibration from occurring and having a high Q-value, an electronic device, an electronic apparatus, and a moving object each equipped with the resonator element are provided. The resonator element is provided with a base section, a vibrating arm extending from the base section, and a groove section having a groove with a bottom formed from a first principal surface of the vibrating arm toward a second principal surface on an opposite side to the first principal surface, and is further provided with a mass section disposed on at least a part of the second principal surface.

### BACKGROUND

1. Technical Field

The present invention relates to a resonator element, an electronic device, an electronic apparatus, and a moving object.

2. Related Art

In the past, angular velocity sensors have been used in an autonomous control technology of a posture of a ship, a plane, a rocket, and so on. Recently, angular velocity sensors are used, for example, for body control in a vehicle, vehicle position detection of a car navigation system, and vibration control correction (so called image stabilization) of a digital camera, a video camera, and a cellular phone. Due to miniaturization of such electronic apparatuses described above, miniaturization and height reduction (lower profile) of the angular velocity sensor are required.

In contrast, if the resonator element having driving vibrating arms and detecting vibrating arms and used for an angular velocity sensor is miniaturized, the area of an electrode provided to each of the vibrating arms is decreased, and therefore, there is a problem that the Q-value is lowered, and the detection sensitivity is deteriorated. Therefore, in JP-A-2009-156832, there is disclosed the fact that by providing a groove section to each of the vibrating arms, the electrical field efficiency is improved to raise the Q-value, and thus the detection sensitivity is improved.

However, if the groove is formed by performing dry etching or the like from one principal surface of the vibrating arm, and the vibrating arm is made to flexurally vibrate in which the vibrating arm is displaced in parallel to the principal surface, the flexural vibration superimposed with a torsional vibration is obtained due to the influence of the bending moment, and there is a problem that the vibration is leaked to the base section for holding the vibrating arm, and the Q-value is lowered. Further, in the case of using the resonator element for the angular velocity sensor, the flexural vibration superimposed with the torsional vibration generated in the driving vibrating arm propagates to the detecting vibrating arm via the base section to vibrate the detecting vibrating arm, and there is a problem that the output signal (a 0-point output) occurs even in the state in which no angular velocity is applied to cause an error. Therefore, the problem to be solved is to inhibit the torsional vibration from occurring in the case of causing the flexural vibration in the vibrating arm provided with the groove formed only from the one principal surface.

### SUMMARY

An advantage of some aspects of the invention is to solve at least a part of the problems described above, and the invention can be implemented as the forms or application examples.

### Application Example 1

This application example is directed to a resonator element including a base section, at least one vibrating arm extending from the base section, and a groove section having a groove with a bottom formed in a direction from a first principal surface of the vibrating arm toward a second principal surface on an opposite side to the first principal surface, in a cross-sectional view in a direction perpendicular to an extending direction of the vibrating arm, a centroid of the vibrating arm is located nearer to the second principal surface than to the first principal surface, and a mass section is disposed on at least a part of the second principal surface.

According to this application example, by disposing the centroid of the cross-section of the vibrating arm at a position nearer to the second principal surface than to the first principal surface, and disposing the mass section on the second principal surface of the vibrating arm on which the groove is not disposed, the distance from the centroid of the cross-section of the vibrating arm to the tip of the groove section and the distance from the centroid of the cross-section of the vibrating arm to the tip of the mass section can be made roughly equivalent to each other in the cross-section of the vibrating arm perpendicular to the extending direction of the vibrating arm. Therefore, in the case of making the vibrating arm flexurally vibrate in the plane, the bending moment caused by the difference in the distance from the centroid of the cross-section of the vibrating arm can be reduced, and thus, it is possible to suppress the generation of the torsional vibration to thereby obtain the resonator element having a high Q-value. Further, in the case of applying the invention to the resonator element of the angular velocity sensor, there is an advantage that the torsional vibration generated in the driving vibrating arms can be suppressed, the 0-point output of the detecting vibrating arms in the state in which no angular velocity is applied can be reduced, and thus an angular velocity sensor with high accuracy can be obtained.

### Application Example 2

This application example is directed to the resonator element according to the application example described above, wherein the mass section is disposed on at least a part of the second principal surface overlapping a thick-wall section constituting the groove section.

According to this application example, by disposing the mass section on a part of the second principal surface overlapping the thick-wall section constituting the groove section, the distance from the centroid of the cross-section of the vibrating arm to the tip of the groove section and the distance from the centroid of the cross-section of the vibrating arm to the tip of the mass section can be made more equivalent to each other. Therefore, in the case of making the vibrating arm flexurally vibrate in the plane, there is an advantage that the bending moment caused by the difference in the distance from the centroid of the cross-section of the vibrating arm can be reduced, and thus, it is possible to suppress the generation of the torsional vibration to thereby obtain the resonator element having a high Q-value.

### Application Example 3

This application example is directed to the resonator element according to the application example described above, wherein the mass section is disposed on at least a part of the second principal surface overlapping a bottom base of the groove section.

According to this application example, by disposing the mass section on a part of the second principal surface overlapping the bottom base of the groove section, the distance from the centroid of the cross-section of the vibrating arm to the tip of the groove section and the distance from the centroid of the cross-section of the vibrating arm to the tip of the mass section can be made roughly equivalent to each other similarly to the case of disposing the mass section on the part of the second principal surface overlapping the thick-wall section. Therefore, in the case of making the vibrating arm flexurally vibrate in the plane, there is an advantage that the bending moment caused by the difference in the distance from the centroid of the cross-section of the vibrating arm can be reduced, and thus, it is possible to suppress the generation of the torsional vibration to thereby obtain the resonator element having a high Q-value.

### Application Example 4

This application example is directed to the resonator element according to the application example described above, wherein the mass section is disposed on at least a part of the first principal surface.

According to this application example, even in the case in which the mass of the mass section on the second principal surface is too high, and the equivalent distance from the centroid of the cross-section of the vibrating arm to the tip of the mass section becomes longer than the distance from the centroid of the cross-section of the vibrating arm to the tip of the groove section, by disposing the mass section on the first principal surface, the distance from the centroid of the cross-section of the vibrating arm to the tip of the groove section and the distance from the centroid of the cross-section of the vibrating arm to the tip of the mass section can be made roughly equivalent to each other. Therefore, in the case of making the vibrating arm flexurally vibrate in the plane, there is an advantage that the bending moment caused by the difference in the distance from the centroid of the cross-section of the vibrating arm can be reduced, and thus, it is possible to suppress the generation of the torsional vibration to thereby obtain the resonator element having a high Q-value.

### Application Example 5

This application example is directed to the resonator element according to the application example described above, wherein a plurality of the grooves is arranged along the extending direction of the vibrating arm.

According to this application example, by arranging the plurality of grooves in series along the extending direction of the vibrating arm, the thick-wall section can be disposed between the grooves. Therefore, the rigidity in the displacement direction is increased in the in-plane flexural vibration, and it is possible to obtain the resonator element high in excitation strength, which is not damaged even if the strong excitation is performed by increasing the applied voltage. Further, since the length of the groove in the extending direction of the vibrating arm can be shortened, there is obtained an advantage that the influence of the bending moment can be reduced, the generation of the torsional vibration is further suppressed, and thus, the resonator element having a high Q-value can be obtained.

### Application Example 6

This application example is directed to the resonator element according to the application example described above, wherein a plurality of the grooves is arranged in the cross-sectional view.

According to this application example, by arranging the plurality of grooves in parallel to each other along the extending direction of the vibrating arm, it is possible to increase the side surfaces, where the electrical charge is generated, perpendicular to the width direction of the vibrating arm, and therefore, there is obtained an advantage that the electrical field efficiency can be enhanced, and the resonator element having a higher Q-value can be obtained.

### Application Example 7

This application example is directed to the resonator element according to the application example described above, wherein the vibrating arm is provided with an electrode, a center of a length of the electrode in the extending direction of the vibrating arm is located nearer to the base section of the vibrating arm than a center of a length of the mass section in the extending direction of the vibrating arm.

According to this application example, it is advantageous to the suppression of the occurrence of the torsional vibration due to the bending moment to dispose the mass section on the tip side of the extending direction of the vibrating arm since the influence of the bending moment due to the groove is more significant on the tip side of the extending direction of the vibrating arm than on the base section side of the vibrating arm. Further, it has an advantage that the resonator element with a high Q-value can be obtained to dispose the excitation electrodes on the base section side of the vibrating arm since the stress due to the vibration is concentrated on the base section side compared to the tip side, and therefore a larger amount of charge can effectively be picked up with the electrode small in area.

### Application Example 8

This application example is directed to the resonator element according to the application example described above, wherein the vibrating arm is provided with a weight section disposed on a tip side in the extending direction.

According to this application example, since the vibrational frequency of the resonator element can be lowered by disposing the weight section on the tip side of the extending direction of the vibrating arm, assuming that the vibrational frequency is the same, there is an advantage that the vibrating arm can be made shorter to achieve miniaturization of the resonator element compared to the resonator element without the weight section.

### Application Example 9

This application example is directed to an electronic device including the resonator element according to the application example described above, and a circuit element.

According to this application example, there is an advantage that there can be obtained the electronic device equipped with the resonator element having a high Q-value and a stable vibrational characteristic.

### Application Example 10

This application example is directed to an electronic apparatus including the resonator element according to the application example described above.

According to this application example, there is an advantage that there can be configured the electronic apparatus equipped with the resonator element inhibiting an unwanted torsional vibration from occurring, and having a high Q-value.

### Application Example 11

This application example is directed to a moving object including the resonator element according to the application example described above.

According to this application example, there is an advantage that there can be configured the moving object equipped with the resonator element inhibiting an unwanted torsional vibration from occurring, and having a high Q-value.

### BRIEF DESCRIPTION OF THE DRAWINGS

The invention will be described with reference to the accompanying drawings, wherein like numbers reference like elements.

FIGS. 1A and 1B are schematic diagrams showing a structure of a resonator element according to a first embodiment of the invention, wherein FIG. 1A is a plan view, and FIG. 1B is a cross-sectional view along the A-A line.

FIGS. 2A and 2B are schematic diagrams for explaining the vibration state of the resonator element in the related art, wherein FIG. 2A is a cross-sectional view of a vibrating arm, and FIG. 2B is a cross-sectional view of the vibrating arm, and shows the vibration state.

FIGS. 3A through 3C are schematic diagrams for explaining the vibration state of the resonator element according to the first embodiment of the invention, wherein FIG. 3A is a cross-sectional view of a vibrating arm, FIG. 3B is a cross-sectional view of an imaginary vibrating arm, and FIG. 3C is a cross-sectional view of the imaginary vibrating arm, and shows the vibration state.

FIGS. 4A and 4B are schematic diagrams of a driving vibrating arm, which show Modified Example 1 of the resonator element according to the first embodiment of the invention, wherein FIG. 4A is a plan view, and FIG. 4B is a cross-sectional view along the B-B line.

FIGS. 5A and 5B are schematic diagrams of a driving vibrating arm, which show Modified Example 2 of the resonator element according to the first embodiment of the invention, wherein FIG. 5A is a plan view, and FIG. 5B is a cross-sectional view along the C-C line.

FIGS. 6A and 6B are schematic diagrams of a driving vibrating arm, which show Modified Example 3 of the resonator element according to the first embodiment of the invention, wherein FIG. 6A is a plan view, and FIG. 6B is a cross-sectional view along the D-D line.

FIGS. 7A and 7B are schematic diagrams showing a structure of a resonator element according to a second embodiment of the invention, wherein FIG. 7A is a plan view, and FIG. 7B is a cross-sectional view along the E-E line.

FIGS. 8A through 8C are schematic diagrams for explaining the vibration state of the resonator element according to the second embodiment of the invention, wherein FIG. 8A is a cross-sectional view of a vibrating arm, FIG. 8B is a cross-sectional view of an imaginary vibrating arm, and FIG. 8C is a cross-sectional view of the imaginary vibrating arm, and shows the vibration state.

FIGS. 9A through 9C are schematic diagrams showing a structure of a resonator element according to a third embodiment of the invention, wherein FIG. 9A is a plan view, FIG. 9B is a cross-sectional view along the F1-F1 line, and FIG. 9C is a cross-sectional view along the F2-F2 line.

FIGS. 10A and 10B are schematic diagrams showing a structure of an electronic device equipped with the resonator element according to the invention, wherein FIG. 10A is a plan view, and FIG. 10B is a cross-sectional view along the G-G line.

FIGS. 11A and 11B are schematic diagrams showing an electronic apparatus equipped with the resonator element according to the invention, wherein FIG. 11A is a perspective view showing a configuration of a mobile type (or a laptop type) personal computer, and FIG. 11B is a perspective view showing a configuration of a cellular phone (including PHS).

FIG. 12 is a perspective view showing a configuration of a digital camera as an electronic apparatus equipped with the resonator element according to the invention.

FIG. 13 is a perspective view showing a configuration of a vehicle as a moving object equipped with the resonator element according to the invention.

### DESCRIPTION OF EXEMPLARY EMBODIMENTS

Some embodiments of the invention will hereinafter be explained in detail based on the accompanying drawings.

### Resonator Element

### First Embodiment

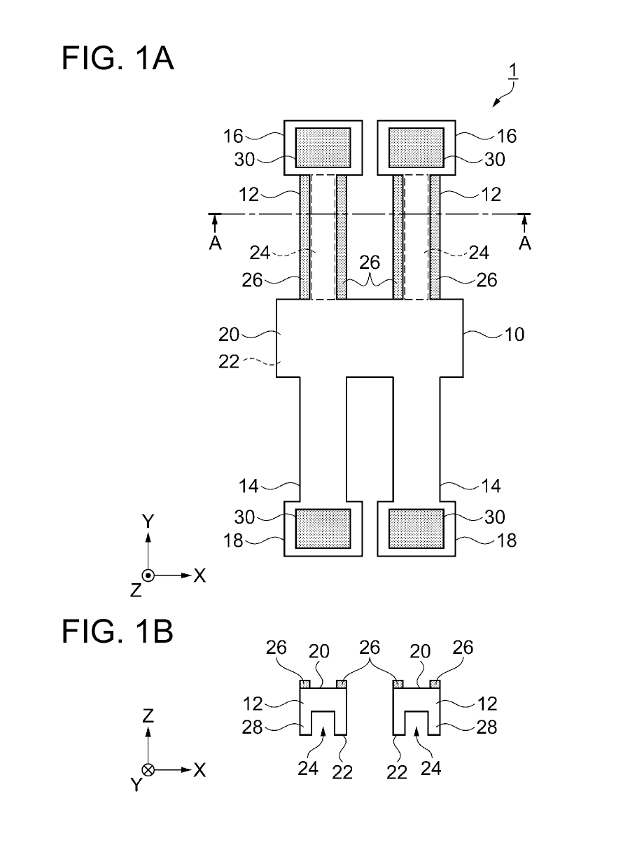

A resonator element having a structure called H-type used for an angular velocity sensor will be cited as an example of a resonator element according to the first embodiment of the invention, and will be explained with reference to FIGS. 1A and 1B.

FIGS. 1A and 1B are schematic diagrams showing a structure of a resonator element 1 according to the first embodiment of the invention, wherein FIG. 1A is a plan view, and FIG. 1B is a cross-sectional view along the A-A line shown in FIG. 1A. It should be noted that driving electrodes and detection electrodes are omitted. Further, in each of the drawings, there are shown X axis, Y axis, and Z axis as three axes perpendicular to each other, and the tip side of the arrow shown in the drawing is defined as “+ side,” and the base end side is defined as “− side” for the sake of convenience of explanation. Further, hereinafter, a direction parallel to the X axis is referred to as an “X-axis direction,” a direction parallel to the Y axis is referred to as a “Y-axis direction,” and a direction parallel to the Z axis is referred to as a “Z-axis direction.” Further, for the sake of convenience of explanation, the explanation will be presented assuming that a surface in the +Z-axis direction is a second principal surface 20, and a surface in the −Z-axis direction is a first principal surface 22 in a planar view viewed from the Z-axis direction.

The resonator element 1 is formed of a piezoelectric material such as quartz crystal, and has a both-side tuning-fork (H-type) flexural resonator element structure, and is provided with a base section 10 located at the center and having a roughly rectangular shape, a pair of driving vibrating arms 12 extending in parallel to each other from the base section 10 arranged on one side of the base section 10, and a pair of detecting vibrating arms 14 extending in parallel to each other arranged on the opposite side to the one side as shown in FIG. 1A.

On surfaces of the driving vibrating arms 12, there are formed drive electrodes (not shown) in order to cause flexural vibrations in the driving vibrating arms 12 in an in-plane direction along the first principal surface 22 and the second principal surface 20, for example, in an X-Y plane parallel to the first principal surface 22 and the second principal surface 20, in a drive mode. On surfaces of the detecting vibrating arms 14, there are formed detection electrodes (not shown) in order to detect a potential difference caused when the detecting vibrating arms 14 make flexural vibrations along a direction intersecting with the first principal surface 22 and the second principal surface 20, for example, in the Z-axis direction perpendicular to the first principal surface 22 and the second principal surface 20, in a detection mode. In the drive mode, when a predetermined alternating-current voltage is applied to the drive electrodes, the driving vibrating arms 12 make the flexural vibrations in directions opposite to each other, namely in directions of getting closer to and away from each other, in the in-plane direction of the X-Y plane.

When the resonator element 1 for the angular velocity sensor rotates around the Y-axis in the longitudinal direction in this state, the driving vibrating arms 12 make the flexural vibrations in out-of-plane directions perpendicular to the first principal surface 22 and the second principal surface 20, namely along the Z-axis direction, opposite to each other due to the action of the Coriolis force generated in accordance with the angular velocity. The detecting vibrating arms 14 make the flexural vibrations also in the directions opposite to each other in the Z-axis direction in the detection mode in resonance with the vibrations of the driving vibrating arms 12 in the Z-axis direction. On this occasion, the vibration directions of the detecting vibrating arms 14 are in reverse phase with the vibration directions of the driving vibrating arms 12.

In the detection mode described above, by taking out the potential difference generated between the detection electrodes of the detecting vibrating arms 14, the angular velocity of the resonator element 1 is obtained.

The vibrating arms 12 are each provided with a groove section 24 having a groove with a bottom formed from the first principal surface 22 toward the second principal surface 20 as an opposite side to the first principal surface 22, and a mass section 26 is disposed in at least a part the second principal surface 20 overlapping a thick-wall section 28 constituting the groove section 24. It should be noted that the groove section 24 and the mass section 26 can also be provided to the vibrating arms 14.

The vibrating arms 12, 14 are respectively provided with weight sections 16, 18 formed at the tip thereof so that a higher-order vibration mode can be inhibited from occurring to thereby stabilize the vibrational frequency even in the case of shortening the length of the vibrating arms 12, 14. Further, by providing the weight sections 16, 18, miniaturization of the resonator element 1 can be achieved, and the vibrational frequency of the vibrating arms 12, 14 can be lowered. It should be noted that the weight sections 16, 18 can have a plurality of widths (lengths in the X-axis direction) as needed, or can also be eliminated.

Further, electrodes 30 are respectively formed on the second principal surfaces 20 of the weight sections 16, 18, and by irradiating these electrodes 30 with a laser beam to partially evaporating the electrodes 30, the vibrational frequencies of the vibrating arms 12, 14 can be adjusted. By adjusting the vibrational frequencies of the pairs of vibrating arms 12, 14 to be equal to each other, the vibration leakage to propagate to the base section 10 can be reduced, and an improvement in the Q-value can be achieved.

The driving vibrating arms 12 are each provided with the groove section 24, which has the groove with the bottom, and is formed in a direction from the first principal surface 22 side toward the second principal surface 20, and elongated along the extending direction (the Y-axis direction). As shown in FIG. 1B, the mass sections 26 each formed of, for example, a member for forming the electrode are each formed in at least a part of the second principal surface 20 overlapping the thick-wall section 28 constituting the groove section 24.

It should be noted that the mass sections 26 can each be made of, for example, a metal material such as gold (Au), gold alloy, platinum (Pt), aluminum (Al), aluminum alloy, silver (Ag), silver alloy, chromium (Cr), chromium alloy, copper (Cu), molybdenum (Mo), niobium (Nb), tungsten (W), iron (Fe), titanium (Ti), cobalt (Co), zinc (Zn), or zirconium (Zr) or an insulating material such as SiO₂ (silicon oxide), AlN (aluminum nitride), or SiN (silicon nitride).

Then, an influence of the groove section 24 disposed on the first principal surface 22 side of the vibrating arm 12 exerted on the vibration will be explained.

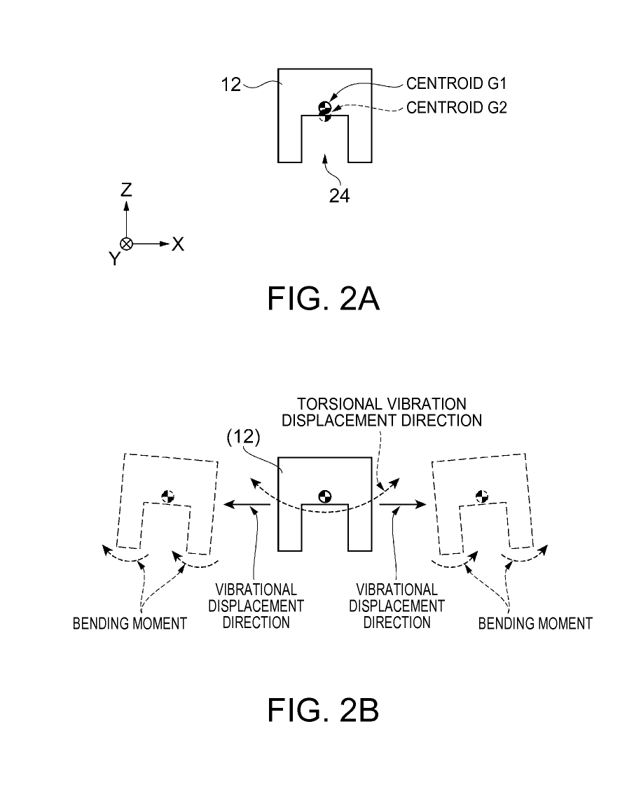

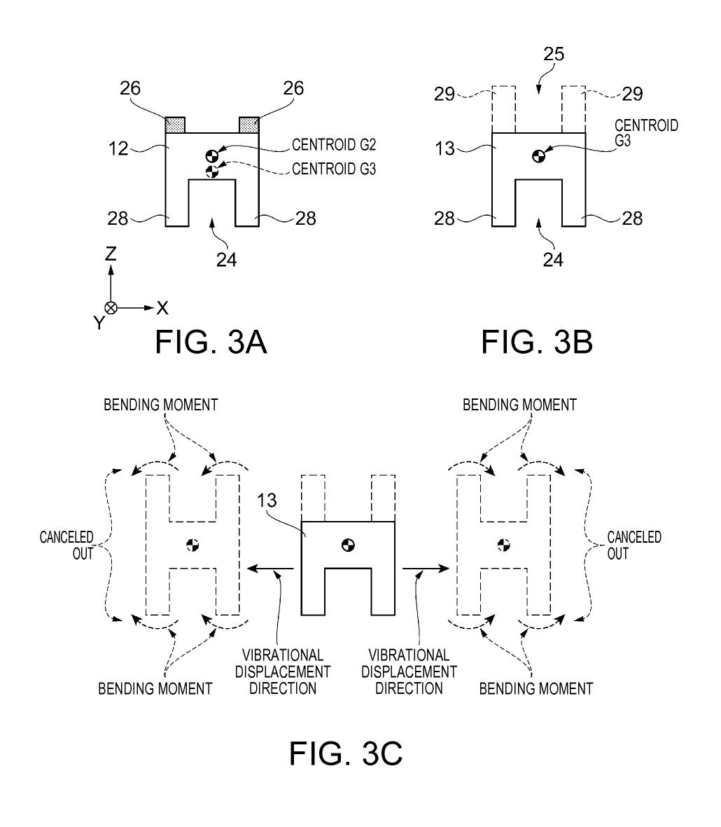

FIGS. 2A and 2B are schematic diagrams for explaining the vibration state of the resonator element in the related art, wherein FIG. 2A is a cross-sectional view of a vibrating arm, and FIG. 2B is a cross-sectional view of the vibrating arm, and shows the vibration state. FIGS. 3A through 3C are schematic diagrams for explaining the vibration state of the resonator element 1 according to the first embodiment of the invention, wherein FIG. 3A is a cross-sectional view of the vibrating arm 12, FIG. 3B is a cross-sectional view of an imaginary vibrating arm 13, and FIG. 3C is a cross-sectional view of the imaginary vibrating arm 13, and shows the vibration state.

Firstly, the vibration state of the resonator element having a groove only provided to one principal surface according to the related art will be explained.

As shown in FIG. 2A, the position of the centroid of the cross-section (the X-Z plane) of the vibrating arm 12 coincides with the centroid G1 at roughly the center in the case in which the groove section 24 is not provided, but is shifted to the centroid G2 deviated in the +Z-axis direction from the rough center if the groove section 24 is provided. Therefore, in the case of making the vibrating arm 12 flexurally vibrate in the X-Y plane, when the vibrating arm 12 is displaced in the +X-axis direction, a bending moment in a counterclockwise direction occurs in a tip portion in the −Z-axis direction of the vibrating arm 12 as shown in FIG. 2B since the tip portion in the −Z-axis direction is longer in the distance from the centroid G2 than a tip portion in the +Z-axis direction of the vibrating arm 12. Further, in contrast, when the vibrating arm 12 is displaced in the −X-axis direction, a bending moment in a clockwise direction occurs in the tip portion in the −Z-axis direction. Therefore, due to the bending moments caused by the difference in the distance from the centroid G2, the flexural vibration previously having the vibrational displacement direction of the vibrating arm 12 only along the X-axis direction turns to the flexural vibration superimposed with a torsional vibration having the displacement direction (torsional vibration displacement direction) added with the rotational movement around the Y axis.

Then, the vibration state of the resonator element 1 according to the first embodiment of the invention provided with the mass sections 26 disposed on the other principal surface not provided with the groove will be explained.

Assuming that the mass sections 26 each having an equivalent mass to that of the thick-wall section 28 constituting the groove section 24 are formed at positions overlapping the respective thick-wall sections 28 as shown in FIG. 3A, the position of the centroid of the cross-section (the X-Z plane) of the vibrating arm 12, which coincides with the centroid G2 in the case with no mass section 26 similarly to the case of FIG. 2A, turns to the centroid G3 deviated in the +Z-axis direction from the centroid G2 if the mass sections 26 are formed. Further, the mass section 26 having the equivalent mass to that of the thick-wall section 28 constituting the groove section 24 can be assumed to correspond to an imaginary thick-wall section 29 constituting an equivalent imaginary groove section 25 on an opposite side to the principal surface provided with the groove section 24, and a cross-section of the imaginary vibrating arm 13 shown in FIG. 3B can be assumed. Therefore, the distance from the centroid G3 becomes roughly equal between the tip of the thick-wall section 28 and a tip of the imaginary thick-wall section 29, and as shown in FIG. 3C, the bending moments generated when making the imaginary vibrating arm 13 flexurally vibrate in the X-Y plane have magnitudes canceled out with each other. Therefore, the difference in the bending moment can be reduced to suppress the torsional vibration caused by the bending moment.

Therefore, by disposing the mass sections 26 on the second principal surface 20 of the vibrating arm 12 not provided with the groove, the distance from the centroid G3 of the cross-section of the vibrating arm 12 to the tip of the thick-wall section 28 and the distance from the centroid G3 to the tip of the mass section 26 can be made roughly equivalent to each other in the cross section (the X-Z plane) of the vibrating arm 12 perpendicular to the direction in which the vibrating arm 12 extends. Therefore, in the case of making the vibrating arm 12 flexurally vibrate in the plane, the bending moment caused by the difference in the distance from the centroid G3 of the cross-section of the vibrating arm 12 can be reduced, and thus, it is possible to suppress the generation of the torsional vibration to thereby obtain the resonator element 1 having a high Q-value. Further, in the case of applying the invention to the resonator element 1 of the angular velocity sensor, there is an advantage that the torsional vibration generated in the driving vibrating arms 12 can be suppressed, the 0-point output of the detecting vibrating arms 14 in the state in which no angular velocity is applied can be reduced, and thus an angular velocity sensor with high accuracy can be obtained.

Although the configuration in which the mass sections 26 are disposed on the second principal surface 20 of each of the vibrating arms 12 is described hereinabove, it is also possible to adopt a configuration of disposing the mass sections 26 on the first principal surface 22 of the vibrating arm 12 in addition to the second principal surface 20. By adopting this configuration, even in the case in which the mass of the mass section 26 of the second principal surface 20 is too high, and the equivalent distance from the centroid G3 of the cross-section of the vibrating arm 12 to the tip of the mass section 26 becomes longer than the distance from the centroid G3 of the cross-section of the vibrating arm 12 to the tip of the thick-wall section 28, by disposing the mass section 26 on the first principal surface 22, the distance from the centroid G3 of the cross-section of the vibrating arm 12 to the tip of the thick-wall section 28 and the distance from the centroid G3 of the cross-section of the vibrating arm 12 to the tip of the mass section 26 can be made roughly equivalent to each other. Therefore, there is an advantage that in the case of making the vibrating arm 12 flexurally vibrate in the plane, the bending moment caused by the difference in the distance from the centroid G3 of the cross-section of the vibrating arm 12 can be reduced, and thus, it is possible to suppress the generation of the torsional vibration to thereby obtain the resonator element 1 having a high Q-value.

Then, Modified Example 1 through Modified Example 3 in the configuration of the mass sections 26 and the groove section 24 of the resonator element 1 according to the first embodiment of the invention will be explained.

Hereinafter, in the description of Modified Examples 1, 2, and 3, the explanation will be presented mainly focused on the differences from the embodiment shown in FIGS. 1A and 1B described above, substantially the same matters are denoted with the same reference symbols, and the explanation thereof will be omitted. Further, since the detecting vibrating arms 14 have the same structure as shown in FIGS. 1A and 1B, the explanation will be presented showing the driving vibrating arms different in structure.

### Modified Example 1

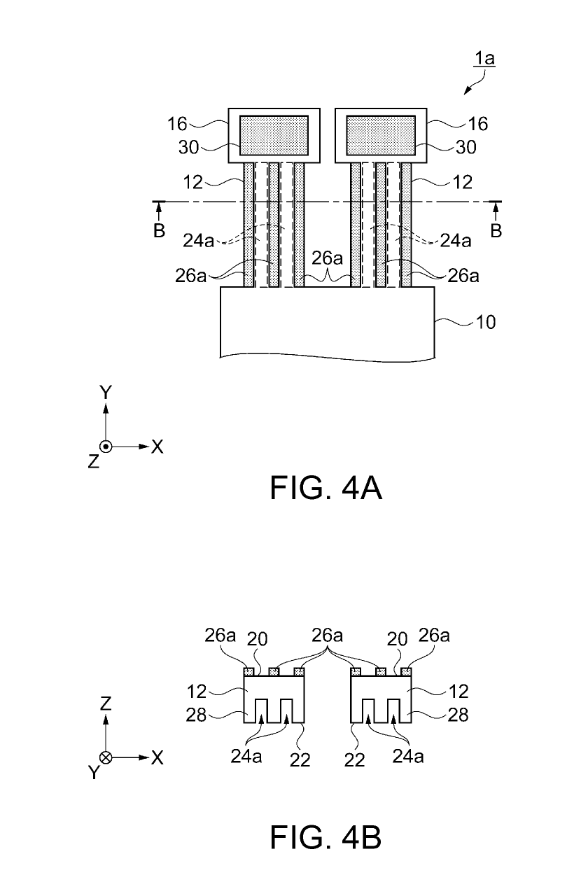

FIGS. 4A and 4B are schematic diagrams showing Modified Example 1 in the configuration of the mass sections 26 and the groove section 24 of the resonator element 1 according to the first embodiment of the invention, wherein FIG. 4A is a plan view, and FIG. 4B is a cross-sectional view along the B-B line in FIG. 4A.

As shown in FIGS. 4A and 4B, a resonator element 1a according to Modified Example 1 is different from the resonator element 1 according to the first embodiment in the point that a plurality of groove sections 24a is arranged in the X-axis direction in the cross-sectional view (an X-Z plane view) of the vibrating arm 12, and the mass sections 26a are respectively disposed on the portions of the second principal surface 20 overlapping the thick-wall sections 28 constituting the plurality of groove sections 24a. By arranging the plurality of groove sections 24a in parallel to each other along the extending direction (the Y-axis direction) of the vibrating arm 12, it is possible to increase the side surfaces (the Y-Z plane), where the electrical charge is generated, perpendicular to the width direction (the X-axis direction) of the vibrating arm 12, and therefore, there is obtained an advantage that the electrical field efficiency can be enhanced, and the resonator element 1a having a higher Q-value can be obtained.

### Modified Example 2

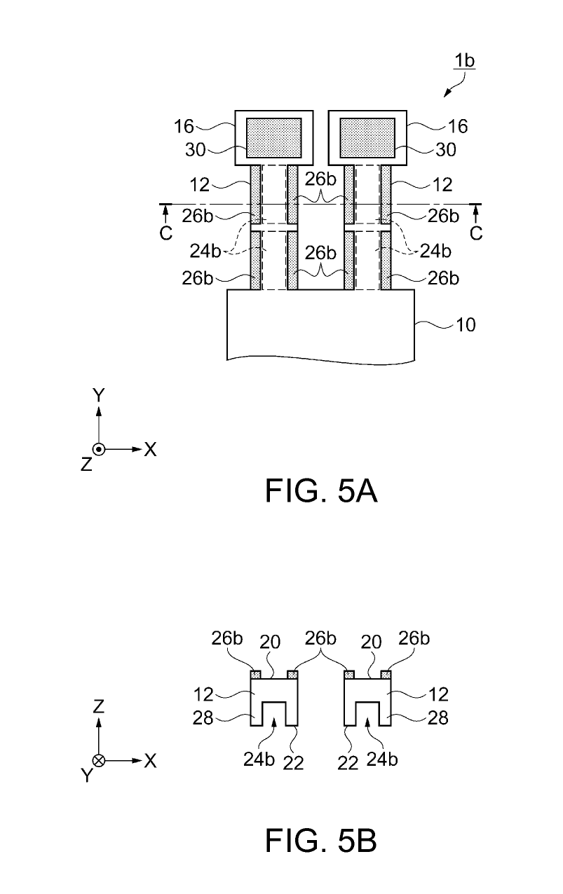

FIGS. 5A and 5B are schematic diagrams showing Modified Example 2 in the configuration of the mass sections 26 and the groove section 24 of the resonator element 1 according to the first embodiment of the invention, wherein FIG. 5A is a plan view, and FIG. 5B is a cross-sectional view along the C-C line in FIG. 5A.

As shown in FIGS. 5A and 5B, a resonator element 1b according to Modified Example 2 is different from the resonator element 1 according to the first embodiment in the point that a plurality of groove sections 24b is arranged in the Y-axis direction in the cross-sectional view in a direction parallel to the extending direction (the Y-axis direction) of the vibrating arm 12, namely in the cross-section (the Y-Z plane), and the mass sections 26b are respectively disposed on the portions of the second principal surface 20 overlapping the thick-wall sections 28 constituting the plurality of groove sections 24b. Since the plurality of groove sections 24b is arranged in series along the extending direction (the Y-axis direction) of the vibrating arm 12, namely since the thick-wall section 28 exists between the groove section 24b and the groove section 24b arranged along the extending direction (the Y-axis direction) of the vibrating arm 12, the rigidity in the displacement direction in the flexural vibration in the X-Y plane is increased, and it is possible to obtain the resonator element 1b high in excitation strength, which is not damaged even if the strong excitation is performed by increasing the applied voltage. Further, since the length in the Y-axis direction of the groove sections 24b can be shortened, there is obtained an advantage that the influence of the bending moment can be reduced, the generation of the torsional vibration is further suppressed, and thus, the resonator element 1b having a high Q-value can be obtained.

### Modified Example 3

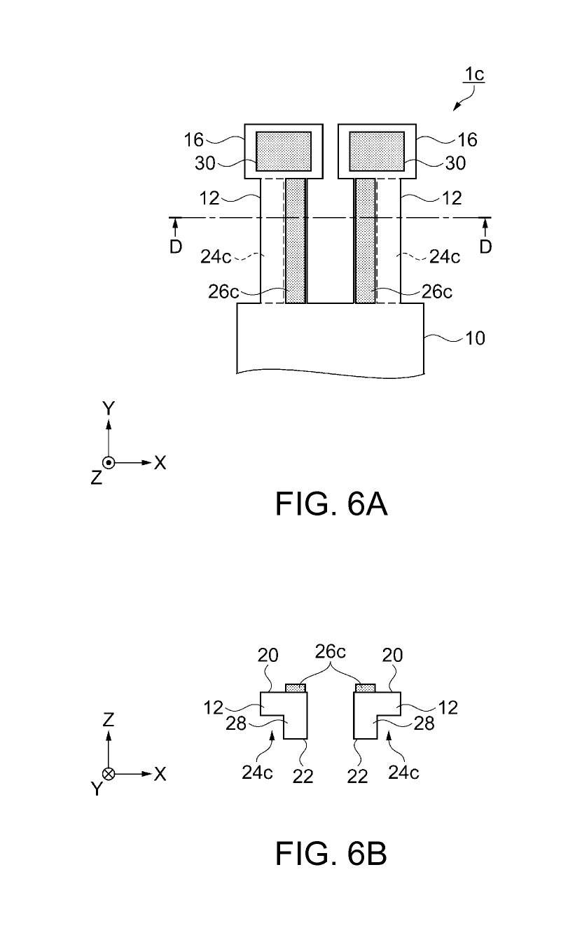

FIGS. 6A and 6B are schematic diagrams showing Modified Example 3 in the configuration of the mass sections 26 and the groove section 24 of the vibration element 1 according to the first embodiment of the invention, wherein FIG. 6A is a plan view, and FIG. 6B is a cross-sectional view along the D-D line in FIG. 6A.

As shown in FIGS. 6A and 6B, a resonator element 1c according to Modified Example 3 is different from the resonator element 1 according to the first embodiment in the point that the groove section 24c of the vibrating arm 12 is constituted by a single thick-wall section 28. However, similarly to the resonator element 1 according to the first embodiment, by disposing the mass section 26c on a part of the second principal surface overlapping the thick-wall section 28, there is obtained an advantage that the influence of the bending moment can be reduced, the generation of the torsional vibration is further suppressed, and thus, the resonator element 1c having a high Q-value can be obtained. It should be noted that although the thick-wall section 28 and the mass section 26c are disposed on the side on which the pair of vibrating arms 12 are close to each other, the invention is not limited to this configuration, but the thick-wall section 28 and the mass section 26c can also be disposed on an opposite side to the side on which the pair of vibrating arms 12 are close to each other.

### Second Embodiment

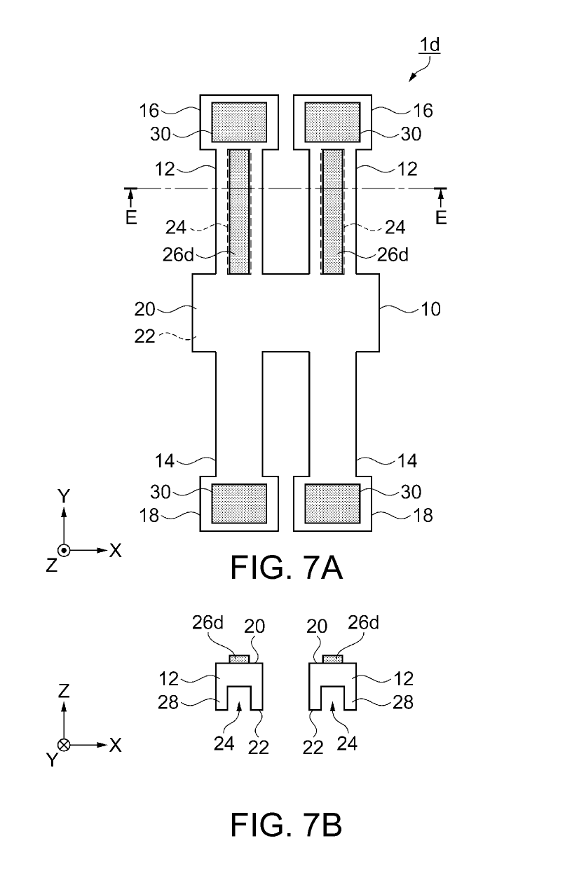

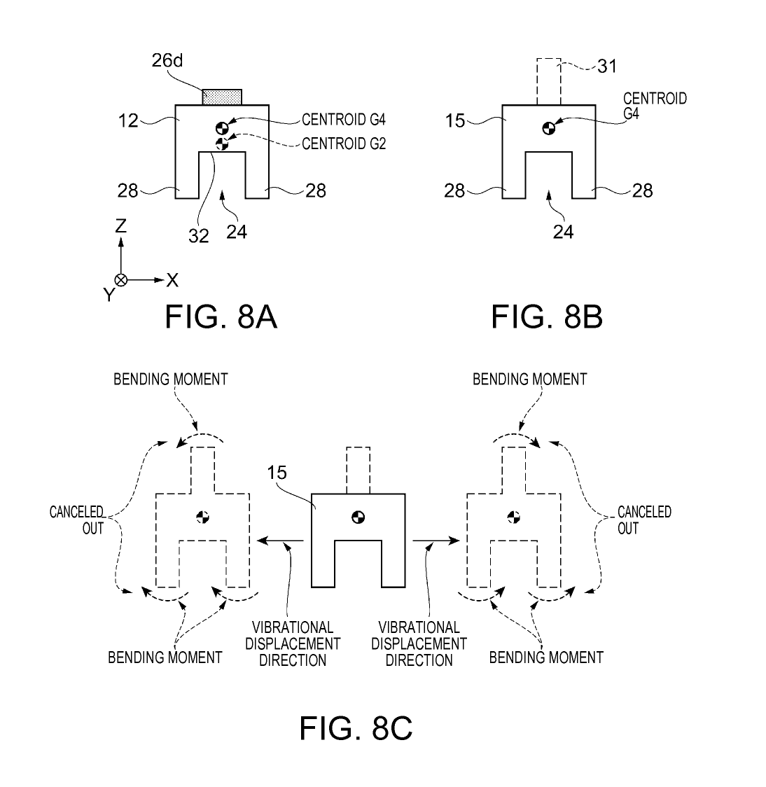

Then, a resonator element 1d according to a second embodiment of the invention will be explained with reference to FIGS. 7A, 7B, and 8A through 8C.

FIGS. 7A and 7B are schematic diagrams showing a structure of the resonator element 1d according to the second embodiment of the invention, wherein FIG. 7A is a plan view, and FIG. 7B is a cross-sectional view along the E-E line in FIG. 7A. FIGS. 8A through 8C are schematic diagrams for explaining the vibration state of the resonator element 1d according to the second embodiment of the invention, wherein FIG. 8A is a cross-sectional view of the vibrating arm 12, FIG. 8B is a cross-sectional view of an imaginary vibrating arm 15, and FIG. 8C is a cross-sectional view of the imaginary vibrating arm 15, and shows the vibration state.

Hereinafter, the resonator element 1d according to the second embodiment will be explained focusing mainly on the differences from the resonator element 1 according to the first embodiment described above, and substantially the same matters are denoted with the same reference symbols, and the explanation thereof will be omitted.

As shown in FIGS. 7A and 7B, the resonator element 1d according to the second embodiment has an outer shape of respectively providing the vibrating arms 12 with the groove sections 24, which is equivalent to the outer shape of the vibrating element 1 according to the first embodiment, but is different in the point that the mass sections 26d are each disposed in at least a part of the second principal surface 20 overlapping a bottom base 32 (see FIG. 8A) of the groove section 24.

Assuming that the mass section 26d having an equivalent mass to that of the two thick-wall sections 28 constituting the groove section 24 is formed at a position overlapping the bottom base 32 as shown in FIG. 8A, the position of the centroid of the cross-section (the X-Z plane) of the vibrating arm 12, which coincides with the centroid G2 in the case with no mass section 26d similarly to the case of FIG. 2A, turns to the centroid G4 deviated in the +Z-axis direction from the centroid G2 if the mass section 26d is formed. Further, the mass section 26d having the equivalent mass to that of the two thick-wall sections 28 constituting the groove section 24 can be assumed as an imaginary thick-wall section 31 having an equivalent mass to that of the two thick-wall sections 28 on the opposite side to the principal surface provided with the groove section 24, and a cross-section of the imaginary vibrating arm 15 shown in FIG. 8B can be assumed. Therefore, by setting the mass of the mass section 26d to a mass equivalent to the distance from the centroid G4 to the tip of the imaginary thick-wall section 31, with which the bending moment generated at the tip of the imaginary thick-wall section 31 becomes roughly equal to the bending moments generated at the tips of the thick-wall sections 28, the bending moments generated when making the imaginary vibrating arm 15 flexurally vibrate in the X-Y plane are also canceled out with each other as shown in FIG. 8C. Therefore, the influence of the bending moment can be reduced, and the torsional vibration caused by the bending moment can be suppressed.

By disposing the mass section 26d on the part of the second principal surface 20 overlapping the bottom base 32 of the groove section 24, similarly to the case of disposing the mass section 26 shown in FIGS. 1A and 1B on the part of the second principal surface 20 overlapping the thick-wall section 28, the distance from the centroid G4 of the cross-section of the vibrating arm 12 to the tip of the thick-wall section 28 and the distance from the centroid G4 to the mass section 26d can be made roughly equivalent to each other. Therefore, there is an advantage that in the case of making the vibrating arm 12 flexurally vibrate in the plane, the bending moment caused by the difference in the distance from the centroid G4 of the cross-section of the vibrating arm 12 can be reduced, and thus, it is possible to suppress the generation of the torsional vibration to thereby obtain the resonator element 1d having a high Q-value.

### Third Embodiment

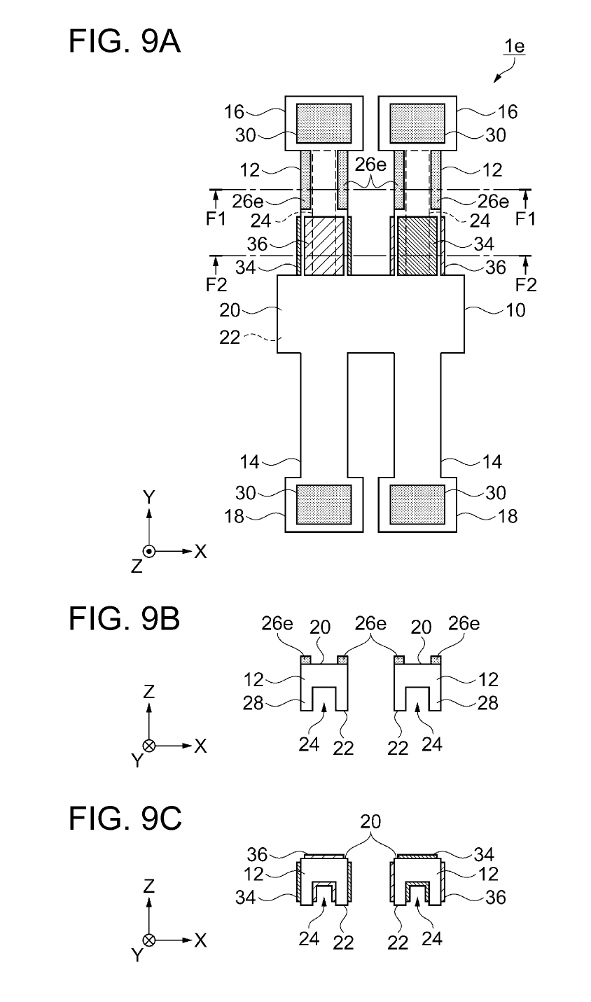

Then, a resonator element 1e according to a third embodiment of the invention will be explained with reference to FIGS. 9A through 9C.

FIGS. 9A through 9C are schematic diagrams showing a structure of a resonator element 1e according to the third embodiment of the invention, wherein FIG. 9A is a plan view, FIG. 9B is a cross-sectional view along the F1-F1 line shown in FIG. 9A, and FIG. 9C is a cross-sectional view along the F2-F2 line shown in FIG. 9A.

Hereinafter, the resonator element 1e according to the third embodiment will be explained focusing mainly on the differences from the resonator element 1 according to the first embodiment described above, and substantially the same matters are denoted with the same reference symbols, and the explanation thereof will be omitted.

As shown in FIGS. 9A through 9C, the resonator element 1e according to the third embodiment has an outer shape of respectively providing the vibrating arms 12 with the groove sections 24, which is equivalent to the outer shape of the vibrating element 1 according to the first embodiment, but the center of the excitation electrodes 34, 36 in the extending direction (in the Y-axis direction) of the vibrating arm 12 is disposed nearer to the base section 10 of the vibrating arm 12 than the center of the mass section 26e in the extending direction (in the Y-axis direction) of the vibrating arm 12. Specifically, the resonator element 1e is different in the point that the excitation electrodes 34, 36 are formed on portions of the surfaces of the vibrating arms 12 near to the base section 10, respectively, and the mass sections 26e are each disposed in at least a part of the second principal surface 20 overlapping the thick-wall section 28 constituting a part of the groove section 24 near to the weight section 16 of the vibrating arm 12.

It is advantageous to the suppression of the occurrence of the torsional vibration due to the bending moment to dispose the mass section 26e on the tip side of the extending direction (the Y-axis direction) of the vibrating arm 12 since the influence of the bending moment due to the groove is more significant on the tip side of the extending direction (the Y-axis direction) of the vibrating arm 12 than on the base section 10 side of the vibrating arm 12. Further, it has an advantage that the resonator element 1e with a high Q-value can be obtained to dispose the excitation electrodes 34, 36 on the base section 10 side of the vibrating arms 12 since the stress due to the vibration is concentrated on the base section 10 side compared to the tip side, and therefore a larger amount of charge can effectively be picked up with the electrode small in area.

### Electronic Device

Then, an electronic device 2, to which the resonator element 1 according to an embodiment of the invention is applied, will be explained.

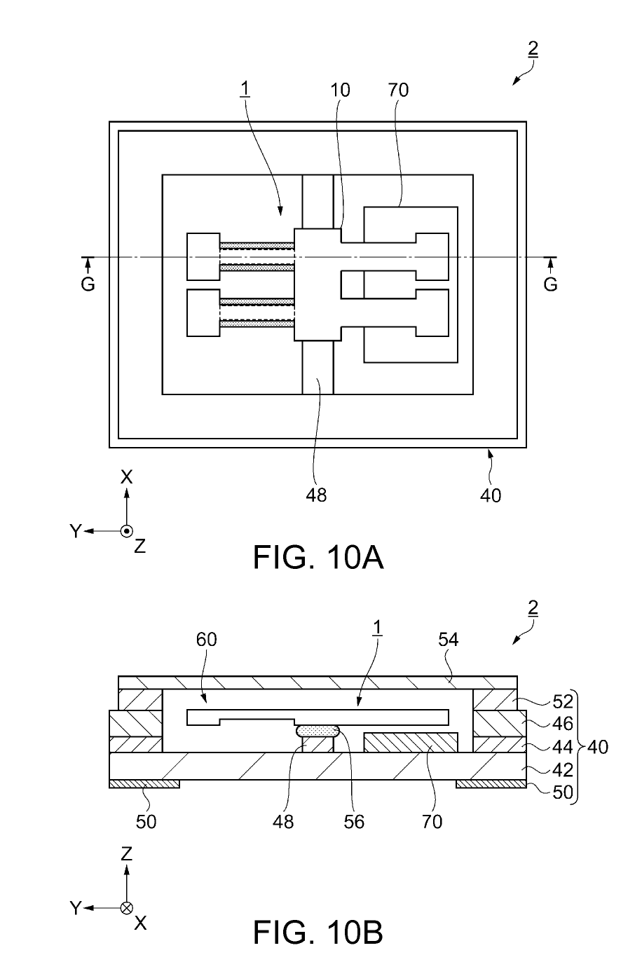

FIGS. 10A and 10B are schematic diagrams showing a structure of the electronic device 2 equipped with the resonator element 1 according to an embodiment of the invention, wherein FIG. 10A is a plan view, and FIG. 10B is a cross-sectional view along the G-G line shown in FIG. 10A. It should be noted that in FIG. 10A, for the sake of convenience of explanation of an internal configuration of the resonator element 1, there is shown a state with a lid member 54 removed. Further, the X axis, the Y axis, and the Z axis are shown as the three axes perpendicular to each other for the sake of convenience of explanation. Further, for the sake of convenience of explanation, in the following explanation, the surface in the +Z-axis direction is referred to as an upper surface, and the surface in the −Z-axis direction is referred to as a lower surface in the plan view viewed from the Z-axis direction.

As shown in FIGS. 10A and 10B, the electronic device 2 is formed of the resonator element 1, a circuit element 70 for oscillating the resonator element 1, a package main body 40 provided with a recessed section for housing the resonator element 1, and the lid member 54 made of glass, ceramic, metal, or the like. It should be noted that the inside of a cavity 60 for housing the resonator element 1 is airtightly sealed so as to have a roughly vacuum reduced-pressure atmosphere.

As shown in FIG. 10B, the package main body 40 is formed by stacking a first substrate 42, a second substrate 44, and a third substrate 46, external terminals 50, and a seal member 52 on each other. A plurality of external terminals 50 is formed on an exterior bottom surface of the first substrate 42. Further, in predetermined positions on the upper surface of the first substrate 42 and the upper surface of the support section 48 of the second substrate 44, there are disposed electrode terminals (not shown) electrically connected to the external terminals 50 and for mounting the circuit element 70 via through electrodes and inter-layer wiring not shown, and electrode terminals (not shown) electrically connected to electrodes for exciting the resonator element 1.

The third substrate 46 is a ring-like member with the central portion removed, and is provided with the cavity for housing the resonator element 1. On an upper circumferential edge of the third substrate 46, there is formed the sealing member 52 such as low-melting-point glass.

The lid member 54 is preferably formed of a light transmissive material such as borosilicate glass, and is bonded with the sealing member 52 to thereby airtightly seal the inside of the cavity 60 of the package main body 40. Thus, it is arranged to make it possible to perform the vibrational frequency adjustment using a mass reduction method by irradiating the electrode 30 (see FIG. 1A) at the tip of the resonator element 1 with the laser beam externally input through the lid member 54 after sealing the package main body 40 with the lid member 54 to thereby partially evaporate the electrode 30 (see FIG. 1A). It should be noted that in the case in which such a vibrational frequency adjustment is not performed, the lid member 54 can be formed of a metal material such as a kovar alloy.

The resonator element 1 housed inside the cavity 60 of the package main body 40 is bonded with the bonding material 56 with the base section 10 positioned on the upper surface of the support section 48 of the second substrate 44. Therefore, since the driving vibrating arms 12 and the detecting vibrating arms 14 are made to vibrate without having contact with the first substrate 42, there is an advantage that it is possible to provide the electronic device 2 equipped with the resonator element 1 having a high Q-value and a stable vibrational characteristic.

### Electronic Apparatus

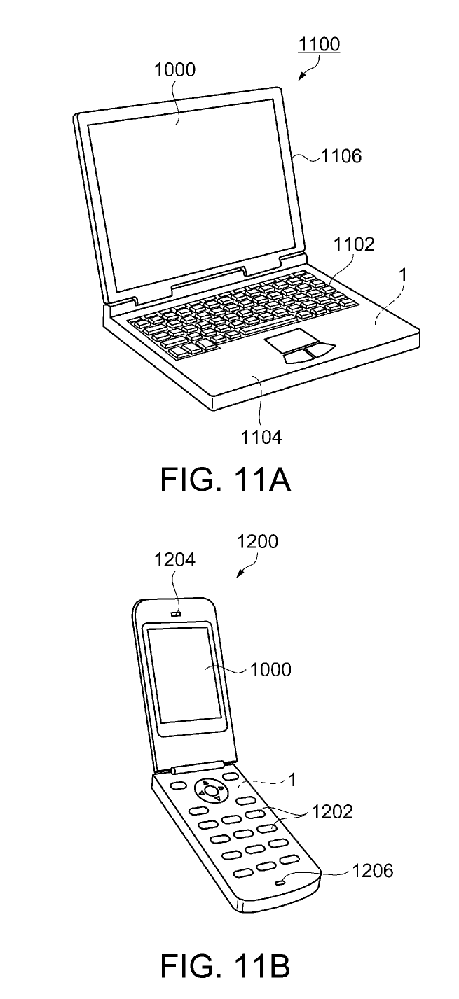

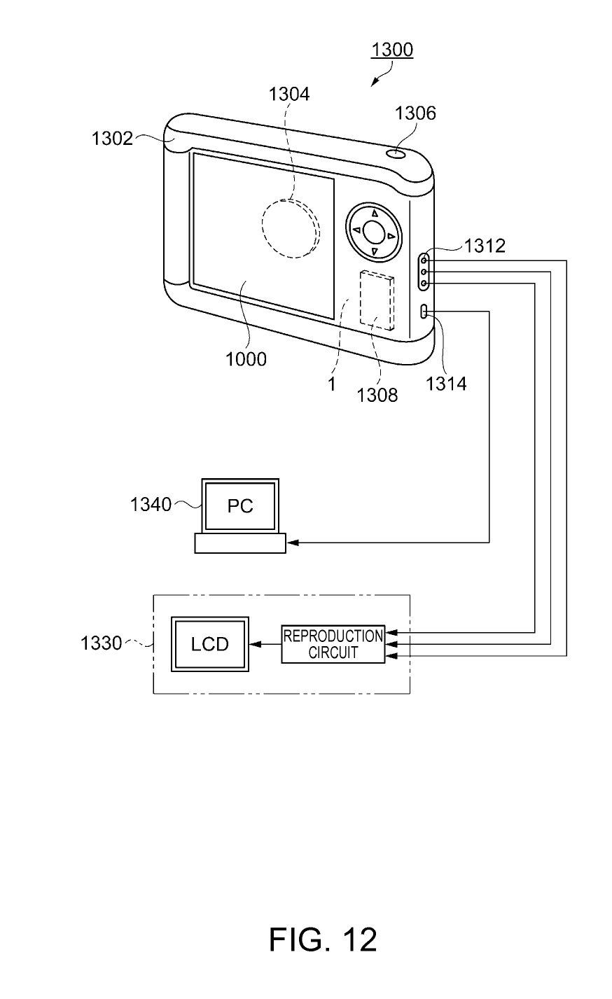

Then, an electronic apparatus, to which the resonator element 1 as an electronic component is applied, according to an embodiment of the invention will be explained with reference to FIGS. 11A, 11B, and 12.

FIGS. 11A and 11B are schematic diagrams showing an electronic apparatus equipped with the resonator element 1 according to an embodiment the invention, wherein FIG. 11A is a perspective view showing a configuration of a mobile type (or a laptop type) personal computer 1100, and FIG. 11B is a perspective view showing a configuration of a cellular phone 1200 (including PHS).

In FIG. 11A, the personal computer 1100 includes a main body section 1104 provided with a keyboard 1102, and a display unit 1106 provided with a display section 1000, and the display unit 1106 is pivotally supported with respect to the main body section 1104 via a hinge structure. Such a personal computer 1100 incorporates the resonator element 1 as an electronic component functioning as a filter, a resonator, a reference clock, and so on.

In FIG. 11B, the cellular phone 1200 is provided with a plurality of operation buttons 1202, an ear piece 1204, and a mouthpiece 1206, and the a display section 1000 is disposed between the operation buttons 1202 and the ear piece 1204. Such a cellular phone 1200 incorporates the resonator element 1 as the electronic component (a timing device) functioning as a filter, a resonator, an angular velocity sensor, and so on.

FIG. 12 is a perspective view showing a configuration of a digital camera 1300 as the electronic apparatus equipped with the resonator element 1 according to an embodiment of the invention. It should be noted that FIG. 12 also shows the connection to an external device in a simplified manner.

The digital camera 1300 performs photoelectric conversion on an optical image of an object using an imaging element such as CCD (Charge Coupled Device) to thereby generate an imaging signal (an image signal).

A case (a body) 1302 of the digital camera 1300 is provided with a display section 1000 disposed on the back surface thereof to have a configuration of performing display in accordance with the imaging signal from the CCD, wherein the display section 1000 functions as a viewfinder for displaying the object as an electronic image. Further, the front side (the reverse side in the drawing) of the case 1302 is provided with a light receiving unit 1304 including an optical lens (an imaging optical system), the CCD, and so on.

When the photographer checks an object image displayed on the display section 1000, and then holds down a shutter button 1306, the imaging signal from the CCD at that moment is transferred to and stored in a memory device 1308. Further, the digital camera 1300 is provided with video signal output terminals 1312 and an input/output terminal 1314 for data communication disposed on a side surface of the case 1302. Further, as shown in the drawing, a television monitor 1330 and a personal computer 1340 are respectively connected to the video signal output terminals 1312 and the input-output terminal 1314 for data communication according to needs. Further, there is adopted the configuration in which the imaging signal stored in the memory device 1308 is output to the television monitor 1330 and the personal computer 1340 in accordance with a predetermined operation. Such a digital camera 1300 incorporates the resonator element 1 as the electronic component functioning as a filter, a resonator, an angular velocity sensor, and so on.

As described above, by making the most use of the resonator element 1 inhibiting the unwanted vibration from occurring, and having a high Q-value as the electronic apparatus, the electronic apparatus having a higher performance can be provided.

It should be noted that, the resonator element 1 as the electronic component according to an embodiment of the invention can also be applied to an electronic apparatus such as an inkjet ejection device (e.g., an inkjet printer), a laptop personal computer, a television set, a video camera, a car navigation system, a pager, a personal digital assistance (including one with a communication function), an electronic dictionary, an electric calculator, a computerized game machine, a workstation, a video phone, a security video monitor, a pair of electronic binoculars, a POS terminal, a medical device (e.g., an electronic thermometer, an electronic manometer, an electronic blood sugar meter, an electrocardiogram measurement instrument, an ultrasonograph, and an electronic endoscope), a fish detector, various types of measurement instruments, various types of gauges (e.g., gauges for a vehicle, an aircraft, or a ship), and a flight simulator besides the personal computer 1100 (the mobile personal computer) shown in FIG. 11A, the cellular phone shown in FIG. 11B, and the digital camera 1300 shown in FIG. 12.

### Moving Object

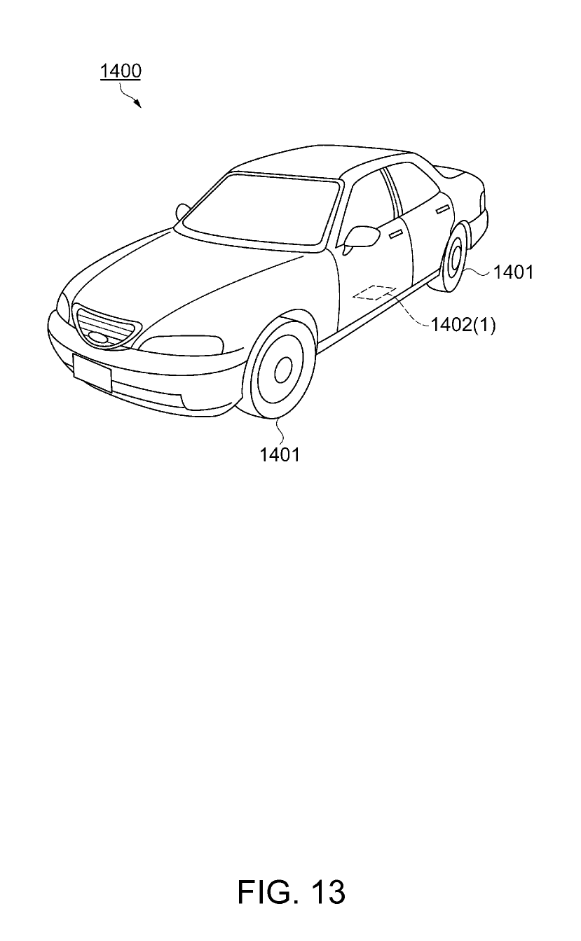

Then, a moving object, to which the resonator element 1 is applied, according to an embodiment of the invention will be explained based on FIG. 13.

FIG. 13 is a perspective view showing a configuration of a vehicle 1400 as a moving object equipped with the resonator element 1 according to an embodiment of the invention.

The vehicle 1400 is equipped with a gyro sensor configured including the resonator element 1 according to the embodiment of the invention. For example, as shown in the drawing, the vehicle 1400 as the moving object is equipped with an electronic control unit 1402 incorporating the gyro sensor for controlling tires 1401. Further, other examples, the resonator element 1 can widely be applied to an electronic control unit (ECU) such as a keyless entry system, an immobilizer, a car navigation system, a car air-conditioner, an anti-lock braking system (ABS), an air-bag system, a tire pressure monitoring system (TPMS), an engine controller, a battery monitor for a hybrid car or an electric car, or a vehicle body attitude control system.

As described above, by making the most use of the resonator element 1 inhibiting the unwanted vibration from occurring, and having a high Q-value as the moving object, the moving object having a higher performance can be provided.

Although the resonator element 1, 1a, 1b, 1c, 1d, and 1e the electronic device 2, the electronic apparatus, and the moving object according to the embodiments of the invention are hereinabove explained based on the embodiments shown in the accompanying drawings, the invention is not limited to these embodiments, but the configuration of each of the components can be replaced with one having an arbitrary configuration with an equivalent function. Further, it is also possible to add any other constituents to the invention. Further, it is also possible to arbitrarily combine any of the embodiments.

The entire disclosure of Japanese Patent Application No. 2013-262136, filed Dec. 19, 2013 is expressly incorporated by reference herein.

What is claimed is:

1. A resonator element comprising:
a base section;
at least one vibrating arm extending from the base section; and
a groove section having a groove with a bottom formed in a direction from a first principal surface of the vibrating arm toward a second principal surface on an opposite side to the first principal surface,
wherein in a cross-sectional view in a direction perpendicular to an extending direction of the vibrating arm,
a centroid of the vibrating arm is located nearer to the second principal surface than to the first principal surface, and
a mass section is disposed on at least a part of the second principal surface.

2. The resonator element according to claim 1, wherein
the mass section is disposed on at least a part of the second principal surface overlapping a thick-wall section constituting the groove section.

3. The resonator element according to claim 1, wherein
the mass section is disposed on at least a part of the second principal surface overlapping a bottom base of the groove section.

4. The resonator element according to claim 1, wherein
the mass section is disposed on at least a part of the first principal surface.

5. The resonator element according to claim 1, wherein
a plurality of the grooves is arranged along the extending direction of the vibrating arm.

6. The resonator element according to claim 2, wherein
a plurality of the grooves is arranged along the extending direction of the vibrating arm.

7. The resonator element according to claim 3, wherein
a plurality of the grooves is arranged along the extending direction of the vibrating arm.

8. The resonator element according to claim 1, wherein
a plurality of the grooves is arranged in the cross-sectional view.

9. The resonator element according to claim 2, wherein
a plurality of the grooves is arranged in the cross-sectional view.

10. The resonator element according to claim 3, wherein
a plurality of the grooves is arranged in the cross-sectional view.

11. The resonator element according to claim 1, wherein
the vibrating arm is provided with an electrode, a center of a length of the electrode in the extending direction is located nearer to the base section of the vibrating arm than a center of a length of the mass section in the extending direction.

12. The resonator element according to claim 1, wherein
the vibrating arm is provided with a weight section disposed on a tip side in the extending direction.

13. The resonator element according to claim 2, wherein
the vibrating arm is provided with a weight section disposed on a tip side in the extending direction.

14. The resonator element according to claim 3, wherein
the vibrating arm is provided with a weight section disposed on a tip side in the extending direction.

15. An electronic device comprising:
the resonator element according to claim 1; and
a circuit element.

16. An electronic apparatus comprising:
the resonator element according to claim 1.

17. A moving object comprising:
the resonator element according to claim 1.
